(19) United States
(12) Patent Application Publication
(10) Pub. No.: US 2014/0054549 A1
(43) Pub. Date: Feb. 27, 2014

(54) GATED CIRCUIT STRUCTURE WITH ULTRA-THIN, EPITAXIALLY-GROWN TUNNEL AND CHANNEL LAYER

(71) Applicants: Wei-Yip LOH, Austin, TX (US); Wei-E WANG, Austin, TX (US)

(72) Inventors: Wei-Yip LOH, Austin, TX (US); Wei-E WANG, Austin, TX (US)

(73) Assignee: SEMATECH, INC., Albany, NY (US)

(21) Appl. No.: 13/592,805

(22) Filed: Aug. 23, 2012

(51) Int. Cl. H01L 29/775; H01L 21/20

(52) U.S. Cl. 257/27; 438/478; 257/E21.09; 257/E29.245

(57) ABSTRACT

A semiconductor device and tunnel field-effect transistor, and methods of fabrication thereof are provided. The device includes first and second semiconductor regions, an intermediate region, and an epitaxial layer. The intermediate region separates the first and second semiconductor regions, and the epitaxial layer extends at least partially between the first and second regions over or alongside of the intermediate region. A gate electrode is provided for gating the circuit structure. The epitaxial layer is disposed to reside between the gate electrode and at least one of the first semiconductor region, the second semiconductor region, or the intermediate region. The epitaxial layer includes an epitaxially-grown, ultra-thin body layer of semiconductor material with a thickness less than or equal to 15 nanometers. Where the semiconductor device is a tunneling field-effect transistor, the intermediate region may be a large band-gap semiconductor region, with a band-gap greater than that of the epitaxial layer.

### BACKGROUND

This invention relates generally to semiconductor devices, and to processes for making semiconductor devices, and more particularly, to tunnel field-effect transistors and methods of making the same.

The sizes of microelectronic devices and other active and passive electrical components are continuously scaled down in attempts to increase device integrated-circuit density. Field-effect transistors are fabricated to provide logic and data-processing functions, among others, for the microelectronic devices built on a wafer. Typically, lithography techniques are used to define the sizes of the field-effect transistors in the devices. As microelectronic device size is continually scaled down, process challenges may increase.

### BRIEF SUMMARY

The present invention relates, in one aspect, to a semiconductor device which includes a circuit structure comprising a first semiconductor region, a second semiconductor region, an intermediate region, and an epitaxial layer. The intermediate region is disposed between the first and second semiconductor regions, and the epitaxial layer extends at least partially between the first semiconductor region and the semiconductor second region over or alongside of the intermediate region. The semiconductor device further includes a gate electrode for gating the circuit structure. The epitaxial layer of the circuit structure is disposed at least partially between the gate electrode and at least one of the first semiconductor region, the intermediate region, and the second semiconductor region.

In another aspect, a tunnel field-effect transistor is provided which includes a circuit structure and a gate electrode for gating the circuit structure. The circuit structure includes a source region, a drain region, and an intermediate region disposed between the source region and the drain region, as well as an epitaxial layer extending at least partially between the source region and the drain region over or alongside of the intermediate region. The epitaxial layer comprises a tunneling region and a channel region of the tunneling field-effect transistor. Further, the epitaxial layer of the circuit structure is disposed at least partially between the gate electrode and at least one of the source region, the intermediate region, or the drain region.

In a further aspect, a method of fabricating a semiconductor device is provided which includes: fabricating a circuit structure. Fabricating the circuit structure includes: providing a first semiconductor region, a second semiconductor region, and an intermediate region disposed between the first and second semiconductor regions; epitaxially growing an epitaxial layer to extend at least partially over or alongside of the intermediate region, wherein the epitaxial layer extends at least partially between the first semiconductor region and the second semiconductor region over or alongside of the intermediate region; and providing a gate electrode for gating the circuit structure, wherein the epitaxial layer of the gated circuit structure is disposed at least partially between the gate electrode and at least one of the first semiconductor region, the intermediate region, or the second semiconductor region.

Additional features and advantages are realized through the techniques of the present invention. Other embodiments and aspects of the invention are described in detail herein and are considered a part of the claimed invention.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a cross-sectional elevational view of a conventional tunnel field-effect transistor;

FIG. 2 is a cross-sectional elevational view of one embodiment of a semiconductor device, and more particularly, a lateral tunnel field-effect transistor, in accordance with one or more aspects of the present invention;

FIG. 3A is a plan view of another embodiment of a semiconductor device, and more particularly, a vertical tunnel field-effect transistor, in accordance with one or more aspects of the present invention;

FIG. 3B is a cross-sectional elevational view of the semiconductor device of FIG. 3A, taken along line 3B-3B thereof, in accordance with one or more aspects of the present invention;

FIG. 4A is a cross-sectional elevational view of one embodiment of a structure obtained during fabrication of a semiconductor device, in accordance with one or more aspects of the present invention;

FIG. 4B is a cross-sectional elevational view of the structure of FIG. 4A, after shallow-trench isolation formation and removal of photoresist, in accordance with one or more aspects of the present invention;

FIG. 4C is a cross-sectional elevational view of the structure of FIG. 4B, after hetero-structural epitaxial deposition to form a stacked circuit structure, in accordance with one or more aspects of the present invention;

FIG. 4D is a cross-sectional elevational view of the structure of FIG. 4C, after fin formation, in accordance with one or more aspects of the present invention;

FIG. 4E is a cross-sectional elevational view of the structure of FIG. 4D, after epitaxial layer formation, in accordance with one or more aspects of the present invention;

FIG. 4F is a cross-sectional elevational view of the structure of FIG. 4E, after gate formation, in accordance with one or more aspects of the present invention;

FIG. 4G is a cross-sectional elevational view of the structure of FIG. 4F, after photoresist patterning to facilitate gate, drain, and source formation, in accordance with one or more aspects of the present invention;

FIG. 4H is a cross-sectional elevational view of a semiconductor device obtained from the structure of FIG. 4G, after contact formation and metallization, in accordance with one or more aspects of the present invention;

FIG. 5A is a partial cross-sectional elevational view of one embodiment of a semiconductor device comprising a vertical tunneling field-effect transistor, in accordance with one or more aspects of the present invention;

FIG. 5B is a partial cross-sectional elevational view of another embodiment of a semiconductor device comprising a vertical tunneling field-effect transistor, in accordance with one or more aspects of the present invention; and

FIG. 6 depicts one embodiment of a flow diagram of a design process which may be employed in semiconductor design and manufacture of semiconductor structures, in accordance with one or more aspects of the present invention.

### DETAILED DESCRIPTION

Generally stated, disclosed herein is a semiconductor device comprising a gated circuit structure, and a method of fabrication thereof. The gated circuit structure, which in one embodiment is a tunneling field-effect transistor (TFET), includes a circuit structure having a first semiconductor region, a second semiconductor region, an intermediate region disposed between and separating the first and second semiconductor regions, and an epitaxial layer extending at least partially between the first and second semiconductor regions over or alongside of the intermediate region. A gate electrode is associated with the circuit structure for gating the circuit structure, and the epitaxial layer of the circuit structure is disposed at least partially between the gate electrode and at least one of the first semiconductor region, the intermediate region, or the second semiconductor region. The epitaxial layer is an epitaxially-grown, ultra-thin body layer of semiconductor material, which has a thickness less than or equal to 15 nanometers in, for example, a direction perpendicular to the gate electrode. The epitaxial layer may be epitaxially grown from one or more of the first semiconductor region, the second semiconductor region, or the intermediate region (that is, where the intermediate region comprises a semiconductor material). In one embodiment, the epitaxial layer is re-grown from each of the first and second semiconductor regions, and the intermediate region, again assuming that the intermediate region comprises a semiconductor material.

In a further embodiment, the circuit structure comprises a hetero-structure, with the epitaxial layer comprising a second conductivity type opposite to a first conductivity type of at least one of the first semiconductor region or the second semiconductor region of the circuit structure. In operation, a channel length through a channel region of the epitaxial layer is related to a thickness of the intermediate region between and separating the first semiconductor region and the second semiconductor region. In a tunneling field-effect transistor implementation, the first semiconductor region of the circuit structure is a source region of the tunneling field-effect transistor, and the second semiconductor region of the circuit structure is a drain region of the tunneling field-effect transistor. In such an implementation, the epitaxial layer comprises a tunneling region and a channel region of the tunneling field-effect transistor, with a tunneling junction residing between the source region and the epitaxial layer, or between the drain region and the epitaxial layer.

In an enhanced implementation of the tunneling field-effect transistor, the intermediate region comprises a large band-gap semiconductor material, which has a band-gap greater than a band-gap of the epitaxial layer. Essentially, the intermediate semiconductor region disposed between the source and drain region functions as an isolating semiconductor region due to its large band-gap. Advantageously, the tunneling field-effect transistor may be fabricated as a vertical tunneling field-effect transistor, wherein the circuit structure comprises a stacked circuit structure, with the first semiconductor region, the second semiconductor region, and the intermediate region disposed in the stack, and the epitaxial layer extending along a sidewall of the stacked circuit structure. Further, the semiconductor device, and more particularly, the tunneling field-effect transistor disclosed herein, has structural simplicity due to the re-growth of the epitaxial layer, which incorporates both a pocket region and an ultra-thin body channel region in a single re-growth process that can easily be employed with non-scale devices (that is, the dimension of the epitaxial layer is not scaled lithographically). In one embodiment, the epitaxial layer is conformally-grown from, for example, exposed surfaces of the first semiconductor region, second semiconductor region, and intermediate region (i.e., where the intermediate region is itself a semiconductor material). The resultant structure advantageously combines both the pocket (or tunneling) region and the channel region in a single layer.

Reference is made below to the drawings, which are not drawn to scale to facilitate ease of understanding, wherein the same reference numbers used throughout different figures designate the same or similar elements.

Conventional tunnel devices typically exhibit poor drive current due to a low tunneling probability and/or poor electrostatic coupling to the gate. A vertical pocket device may increase the gate coupling and minimize lateral drain field effects, but may involve significant process complexity. Planar pockets, with a tunneling pocket next to the channel, pose significant process challenges, and typically involve difficult alignment processes.

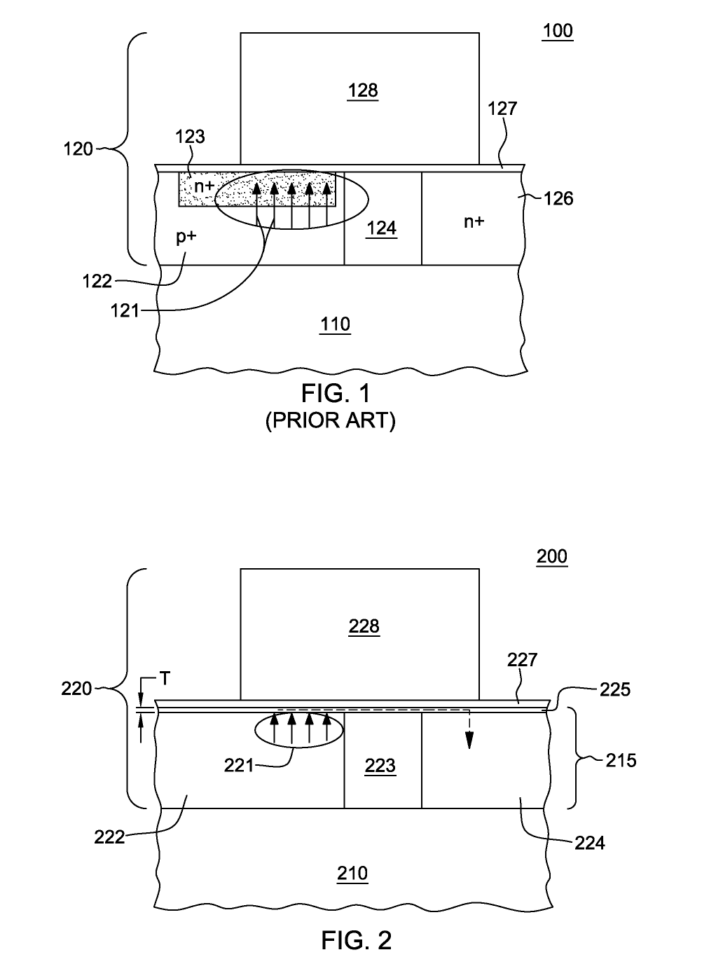

By way of example, FIG. 1 depicts a conventional semiconductor device 100 comprising a tunnel field-effect transistor 120 disposed over an isolation region 110, such as a buried oxide (BOX). The tunnel field-effect transistor (TFET) includes, in the depicted embodiment, a p+ source region 122, an intrinsic region 124, an n+ drain region 126, and a gate 128 disposed over at least the source and intrinsic regions 122, 124. An n+ tunneling region 123 is provided within source region 122, and gate region 128 is separated from the source and drain regions via a gate dielectric 127. When gated on, carriers 121 flow from the source region 122 to the tunneling region 123, and subsequently through the intrinsic region 124 to the drain region 126.

The semiconductor device of FIG. 1 comprises a planar circuit structure, wherein the source and drain regions are in a common plane. This arrangement is ideal for MOSFET formation, but makes formation of the typical tunneling pocket difficult and complex. In particular, formation of the tunneling pocket in a planar TFET such as depicted in FIG. 1 requires use of a hard block mask and an overlap of the pocket to the gate defined by an overlap margin of the gate mask to the block mask. This is highly dependent on alignment and lithography capabilities. Even small misalignments can cause significant differences in device characteristics.

In comparison, disclosed herein is a simpler fabrication process for a gated circuit structure that comprises an epitaxial layer extending at least partially between the first and second semiconductor regions of the circuit structure adjacent to, for example, over or alongside of, the intermediate region separating the first and second regions. The epitaxial layer is disposed at least partially between the gate electrode and one or more of the first semiconductor region, the intermediate region, or the second semiconductor region.

FIG. 2 depicts one embodiment of a semiconductor device, generally denoted 200, comprising a gated circuit structure 220 fabricated, for example, over an isolation region 210, such as a BOX layer or substrate. In the depicted embodiment, the gated circuit structure comprises a lateral circuit structure 215 which includes a first semiconductor region 222, an intermediate region 223, and a second semiconductor region 224, with an overlying epitaxial layer 225. Epitaxial layer 225 comprises an ultra-thin body layer, for example, less than 15 nanometers in thickness ‘T’, such as in the range of 5-10 nanometers in thickness. In one embodiment, the first semiconductor region 222 is a source region, the intermediate region 223 is an isolating semiconductor region, and the second semiconductor region 224 is a drain region of a tunneling field-effect transistor. In this example, intermediate region 223 is an isolating semiconductor region by requiring the region to have a greater band-gap than a band-gap of the overlying epitaxial layer 225. Advantageously, with intermediate region 223 being an isolating semiconductor region, epitaxial layer 225 may be eptiaxially-grown in a single epi-growth process from the source region, the isolating semiconductor region, and the drain region.

By way of specific example, first semiconductor region 222 may comprise a p+ source region, and second semiconductor region 224 an n+ drain region, with epitaxial layer 225 being an n+, horizontally-extending tunneling and channel layer, grown to at least partially overlie the intermediate region, and in one embodiment, to fully overlie the intermediate region and at least partially overlie one or both of the source region and the drain region. A gate or gate electrode 228 is associated with lateral circuit structure 215, and separated from epitaxial layer 225 via a gate dielectric 227. In operation, when gated on, carriers 221 tunnel from the p+ source region 222 into the n+ epitaxial layer 225, and pass through the gated channel region of the epitaxial layer 225 into drain region 224. Note that in this example, intermediate region 223 comprises an isolating region, whether semiconductor or insulator. If intermediate region 223 is a semiconductor region, then the isolating semiconductor region has a higher band-gap than that of the epitaxial layer 225, and thus, carriers pass around the intermediate region and flow through the gated channel region of epitaxial layer 225.

Disclosed herein is a gated tunneling device which may be employed, for example, in forming very low-power electronic switches. Unlike conventional MOSFET devices, tunneling devices (such as those disclosed herein) use direct tunneling of carriers from conduction band to valance, or from valance band to conduction band, without going through a thermonic barrier. This mode of conduction allows tunnel devices to achieve very steep turn on, which in turn means that very low voltage (or power) is required to turn on the device.

As noted, the alignment of the pocket to the source and gate in a conventional, lateral tunnel MOSFET is problematic, since alignment of the pocket to the source and gate can be difficult. Another issue with conventional TFET is the large bulk leakage current that occurs due to the use of a thick semiconducting material for the intrinsic channel between the source and drain regions. Advantageously, as noted above with respect to the embodiment of FIG. 2, a tunnel field-effect transistor in accordance with one or more aspects of the present invention replaces the intrinsic semiconductor region between the source and drain in a conventional MOSFET (such as depicted in FIG. 1) with an isolating region, such as an isolating semiconductor region that more fully keys off the off-state leakage current. As used herein, an isolating semiconductor region refers to a semiconductor region having a larger band-gap than the band-gap of the overlying or adjacent epitaxial layer. In one specific example, the isolating semiconductor region may have a band-gap of, for example, 0.67 eV (for InAsSb) to 3.09 eV (for AlAs). The thin epitaxial layer, grown above and extending at least partially between the source and drain regions, comprises the pocket or tunneling region, as well as a self-aligned, ultra-thin body channel with good channel length control. In one implementation, the channel length is determined by a thickness in the intermediate region separating the source region and the drain region of the circuit structure. Note also that in the above example, a hetero-structure may be readily formed between the source region and the epitaxial layer, with the epitaxial layer comprising a second conductivity type opposite from the first conductivity type of the source region.

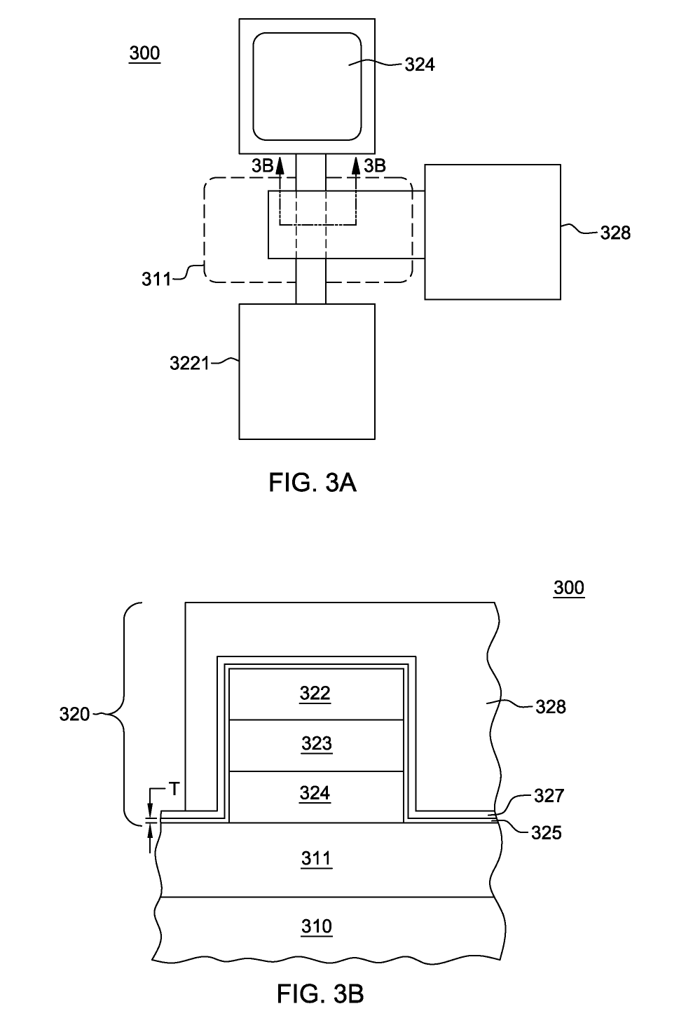

FIGS. 3A & 3B depict another embodiment of a semiconductor device, generally denoted 300, in accordance with one or more aspects of the present invention. In this embodiment, the semiconductor device comprises a vertical tunneling field-effect transistor (TFET), with a device region 311 disposed, for example, over an isolation region 310, such as a BOX layer. In the depicted embodiment, the gated circuit structure 320 includes a fin-shaped, stacked circuit structure comprising a first semiconductor region 322, an intermediate region 323, and a second semiconductor region 324. An epitaxially-grown, ultra-thin layer of semiconductor material, referred to herein as epitaxial layer 325, has been conformally formed over the stack structure, including along the sidewall(s) thereof.

In one embodiment, this epitaxial layer 325 has a thickness ‘T’ less than or equal to 15 nanometers, and more particularly, a thickness ‘T’ in the range of 5-10 nanometers. A gate or gate electrode 328 is associated with the stacked circuit structure, and separated from the epitaxial layer 325 by a gate dielectric 327. Note that in this embodiment, epitaxial layer 325 extends along the sidewall(s) of the stacked circuit structure. By way of specific example, first semiconductor region 322 comprises a source region, intermediate region 323 comprises an isolating semiconductor region (or body) having a greater band-gap of that of the epitaxial layer 325, and second semiconductor region 324 comprises a drain region of the vertical tunneling field-effect transistor. In one implementation, the source region is a p+ source region and the epitaxial layer 325 is n+ doped layer, and a hetero-structure being defined between the epitaxial layer and the source region. In addition to providing a tunneling region, the epitaxial layer also forms an ultra-thin body layer of the tunneling field-effect transistor, which allows for low leakage current and higher tunnel current employing the concept of a tunneling pocket in a three-dimensional FinFET.

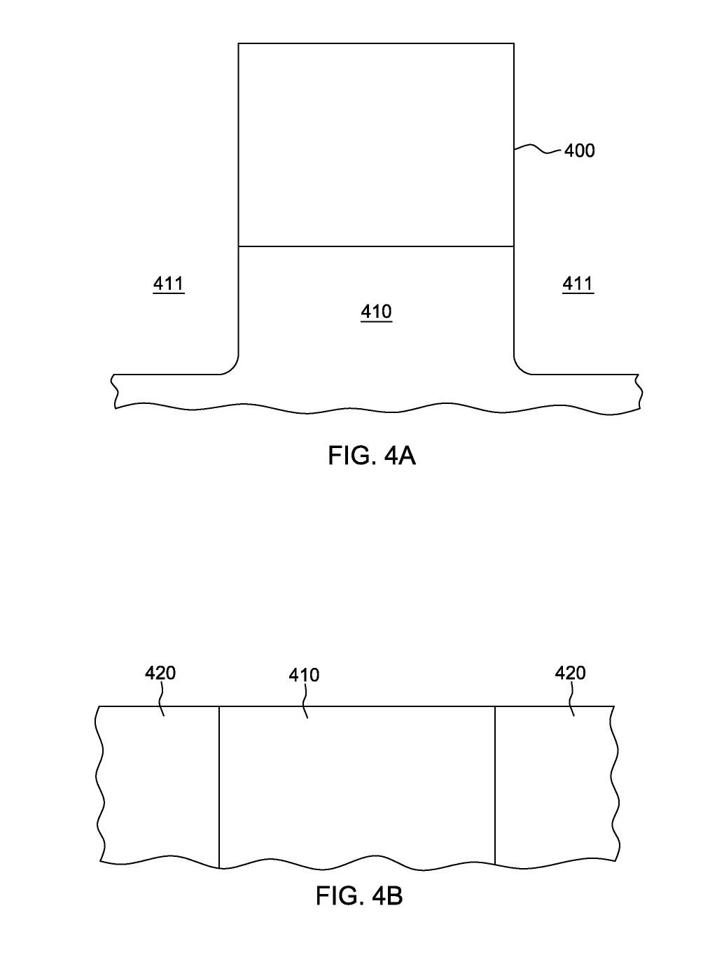

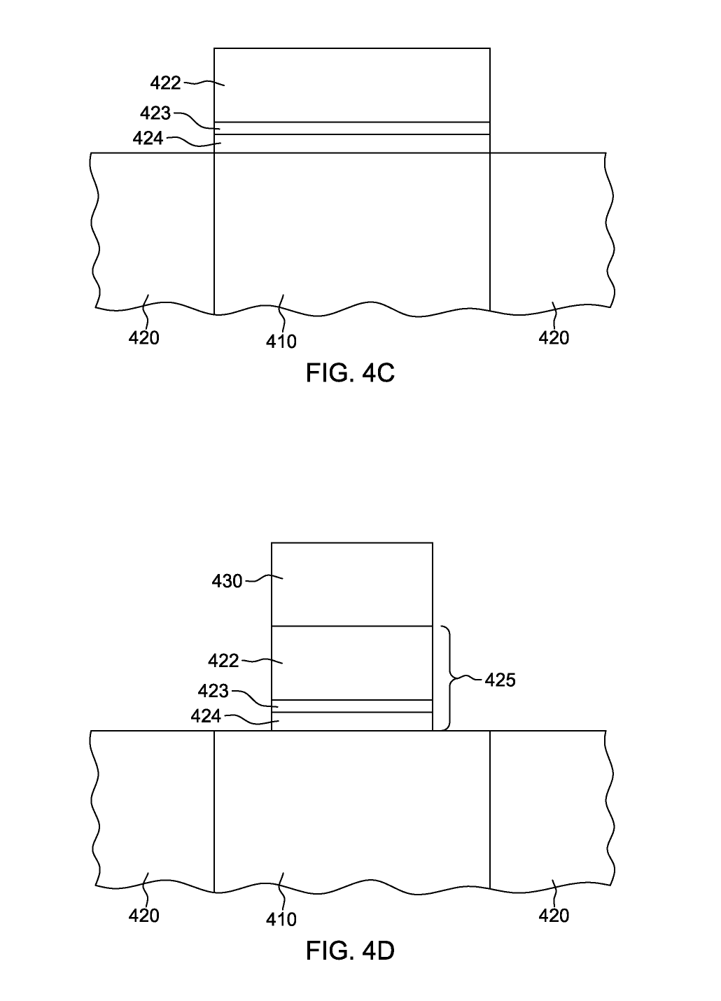

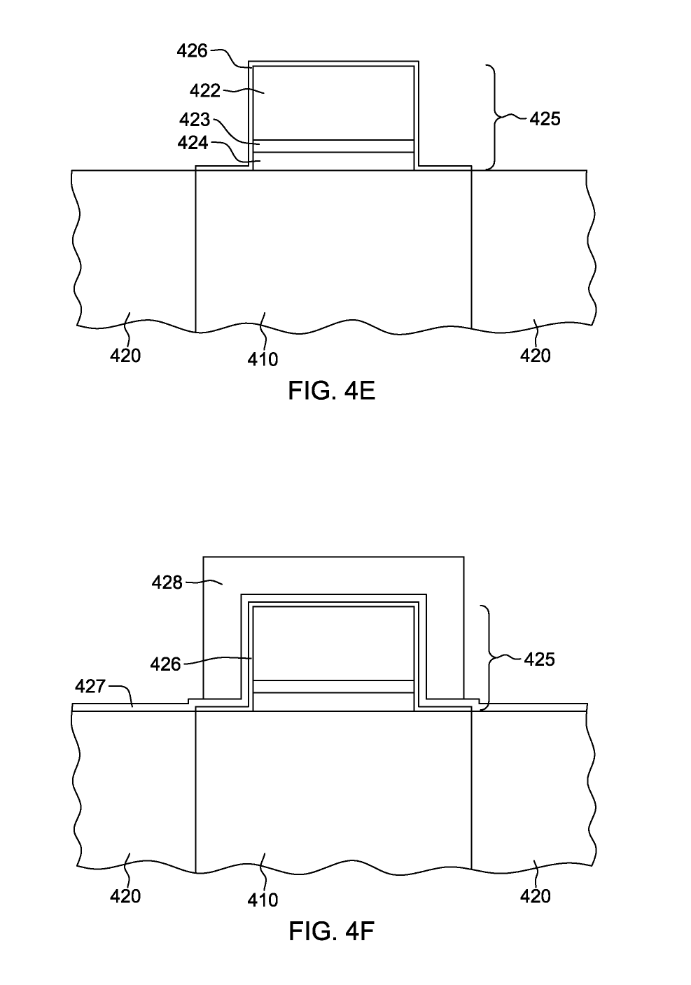

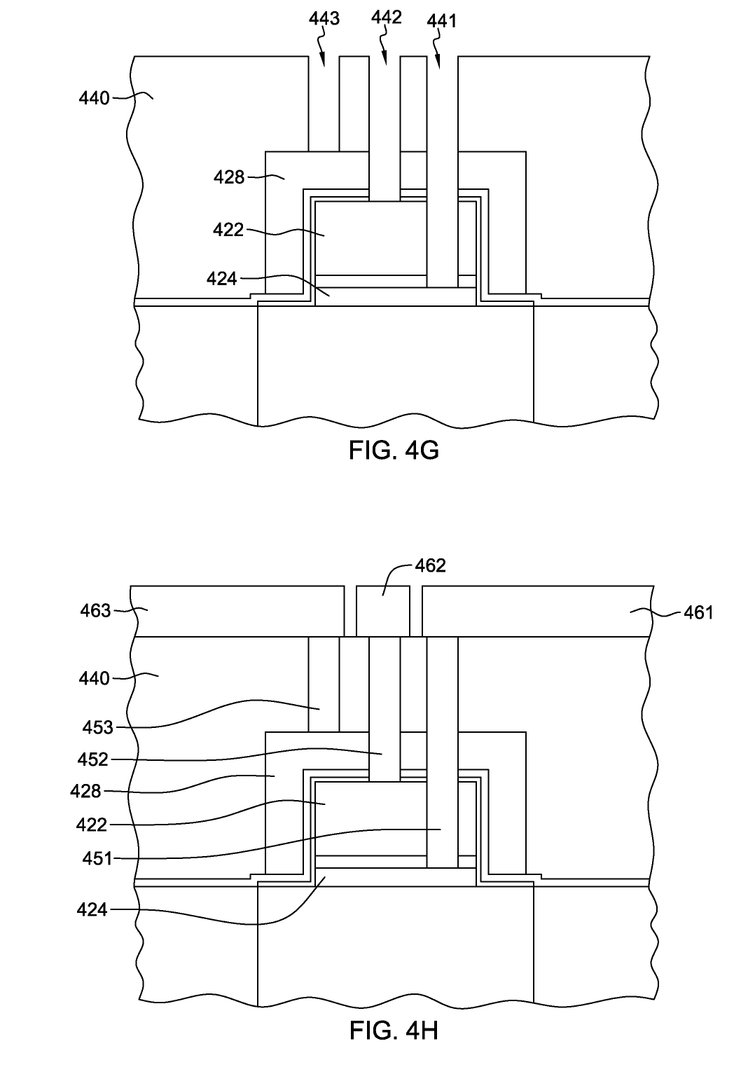

FIGS. 4A-4H depict one embodiment for fabricating a vertical, tunneling field-effect transistor such as that depicted in FIGS. 3A & 3B.

In FIG. 4A, an intermediate structure is depicted wherein a substrate 410 is etched with openings 411 to facilitate defining shallow trench isolation regions 420, which are illustrated (by way of example) in FIG. 4B. In one embodiment, substrate 410 resides below a patterned photoresist 400 during the etching process, and may be an insolating or large band-gap substrate. Specific examples of substrate 410 include InP or InAlAs semiconductor material. A high-density plasma oxide fill and a chemical mechanical polishing process may be employed in providing the shallow trench isolation regions 420 depicted in FIG. 4B.

In FIG. 4C, a hetero-structure epitaxial deposition has been employed to define a stacked circuit structure comprising a drain region 424, an isolating semiconductor region 423, and a source region 422. Note that known epitaxial growth or deposition techniques may be employed in creating the mesa or stacked semicondcutor structure illustrated in FIG. 4C. In this implementation, the intermediate region between the source region 422 and drain region 424, is a semiconductor region referred to herein as the isolating semiconductor region 423. However, in alternate implementations, this region could be an insulator material, rather than a semiconductor material. Further, thickness within the stack of the isolating semiconductor region 423 may vary, with the channel length through the epitaxial layer to be subsequently formed being correlated to the thickness of the intermediate region between the source and drain regions of the stacked circuit structure.

In FIG. 4D, a photoresist 430 has been applied and patterned to facilitate formation of a stacked fin structure 425 by etching the stack structure of FIG. 4C, as illustrated.

In FIG. 4E, an epitaxial layer 426 has been formed. In one embodiment only, this epitaxial layer 426 is epitaxially-grown from the semiconductor material comprising substrate 410, drain region 424, isolating semiconductor region 423, and source region 422, and the layer overlies or is disposed alongside of those regions. As illustrated, the epitaxial layer 426 extends along the sidewall(s) of the stacked circuit structure 425. This epitaxial layer 426 is an ultra-thin layer of semiconductor material, for example, having a thickness less than or equal to 15 nanometers in a dimension of epitaxial growth, and more particularly, in a range of 5-10 nanometers.

In FIG. 4F, a dielectric layer 427 and gate structure 428 have been formed, in one example, by an atomic layer deposition (ALD) of high K dielectric, followed by a gate metallization defined by photolithography and etching.

In FIG. 4G, conventional CMOS processes are employed to define patterned openings 441, 442 & 433 in a photoresist 440 exposing (in this example) drain region 424, source region 422, and gate electrode 428, respectively.

FIG. 4H depicts the structure of FIG. 4G after formation of electrical connects 451, 452, and 453 to the drain region, the source region, and gate electrode, respectively. These electrical connects 451, 452, 453 may be formed, for example, by TiN or tungsten deposition, followed by chemical mechanical planarization. Patterned metallization is then applied to establish metal interconnects 461, 462, and 463, electrically connected to drain region 424, source region 422, and gate electrode 428 via the respective electrical connects 451, 452, and 453.

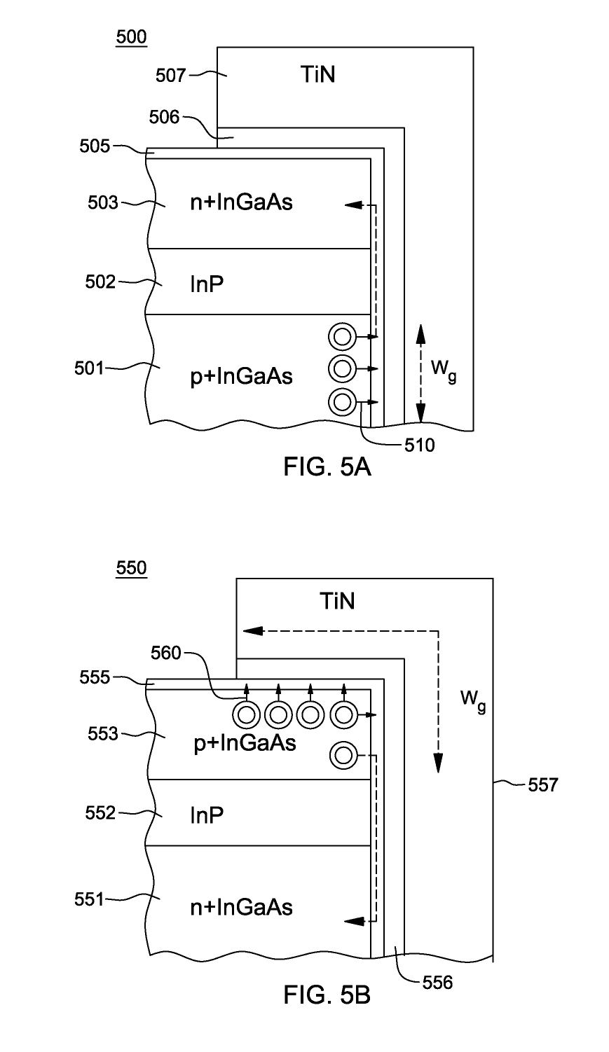

FIGS. 5A-5B depict two detailed examples of a semiconductor structure comprising a vertical tunneling field-effect transistor, in accordance with one or more aspects of the present invention. In FIG. 5A, the semiconductor device 500 includes a stacked circuit structure comprising a source region 501, an isolating semiconductor region 502, and a drain region 503 with an overlying epitaxial layer 505, formed over and along the sidewall of the stacked circuit structure. A gate dielectric 506 separates gate electrode 507 from the stacked circuit structure. In this embodiment, carriers 510 pass from source region 501 through the epitaxial layer 505 to drain region 503. The gate tunneling width (W_{g}) is illustrated in this example as being correlated to the vertical thickness of source region 501. By way of specific example, source region 501 may comprise a p+ InGaAs semiconductor region, isolating semiconductor region 502 may comprise an InP semiconductor region, and drain region 503 may comprise an n+ InGaAs semiconductor region.

As with the examples above, epitaxial layer 505 is assumed to comprise an epitaxially-grown, ultra-thin layer of semiconductor material. This ultra-thin body layer of semiconductor material may have a thickness, for example, in the range of 5-10 nanometers. In one implementation, the epitaxial layer may be eptiaxially-grown along the sidewall of the stacked circuit structure from one or more of the semiconductor material of source region 501, isolating semiconductor region 502, and drain region 503. As with the above examples, the isolating semiconductor region is assumed to have a larger band-gap than that of the epitaxial layer, and the epitaxial layer has a different conductivity type from that of the source region or the drain region, which are themselves of different conductivity type.

In FIG. 5B, the top and bottom electrodes have been interchanged by reversing the order of the layer growth. In particular, in FIG. 5B, a semiconductor device 550 is illustrated comprising a vertical tunneling field-effect transistor, wherein the stacked structure includes a drain region 551, an isolating semiconductor region 552, and a source region 553 with an overlying epitaxial layer 555 over and along the sidewall of the stack structure. A gate dielectric 556 separates gate electrode 557 from the stacked circuit structure. By way of specific example, drain region 551 may comprise an n+ InGaAs semiconductor region, isolating semiconductor region 552 may comprise an InP semiconductor region, and source region 553 may comprise a p+ InGaAs semiconductor region. As illustrated, carriers 560 migrate into epitaxial layer 555 and through the tunneling region of the layer to drain region 551. Note in this example that the gate tunneling width (W_{g}) is larger for the vertical tunneling field-effect transistor of FIG. 5B than for the embodiment of FIG. 5A. When gate tunneling width W_{g} is greater than approximately 30 nm, the tunneling current becomes limited by the channel resistance within the epitaxial layer and both structures behave similarly. The vertical tunneling field-effect transistor of FIG. 5A advantageously has a more uniform electrical field across the junction between the source region and the epitaxial layer.

Those skilled in the art will note that disclosed herein is a semiconductor device, and in certain embodiments, a tunneling field-effect transistor, wherein an epitaxial layer is provided to extend at least partially between a first and second semiconductor region separated by an intermediate region of the device. The epitaxial layer extends over or alongside of the intermediate region and is, in one example, an epitaxially-grown, ultra-thin body layer of semiconductor material, having a thickness less than or equal to 15 nanometers, and in particular, a thickness in the range of 5-10 nanometers. The epitaxial deposition of the epitaxial layer, which comprises a tunneling region and a channel region, can be of another material than the source region or the drain region. This will form, for example, a hetero-structure source to epitaxial layer, which will reduce the tunneling effective band-gap, and hence improve tunneling current.

Also disclosed herein is an ability to form a vertical tunneling field-effect transistor using non-implant techniques coupled with hetero-structure junctions in a simple and straightforward fabrication process. Inclusion of a less heavily doped epitaxial layer allows high tunneling current realization, while minimizing off-state leakage. Usage of an ultra-shallow doping technique, such as mono-layer doping, plasma doping, in situ MBE doping, etc., may be employed to ensure full depletion of the doped region, allowing for a respectable off-state leakage at low gate bias. The hetero-structure of the source and channel provides for modulation of the effective tunneling band-gap, and hence improves tunneling current.

As a specific example, a tunneling field-effect transistor may conventionally include a semiconductor substrate, such as silicon, with impurity doped source and drain regions separated by an intermediate region. Conventionally, the intermediate region is a channel region or intrinsic region of the transistor, which is controlled electrostatically by a gate stack including a dielectric and metal electrode. The tunnel drive current which describes the current flowing from the source to the drain in such a configuration is controlled by the gate potential, and depends on tunneling probability between the source and gate controlled channel region.

In contrast, in accordance with aspects of the invention disclosed herein, an epitaxial layer is formed comprising tunneling and channel regions of the transistor. The epitaxial layer may be a similar material to the underlying source and/or drain regions, or of different material, to form a hetero-structure. Forming a hetero-structure may increase the tunneling probability, while suppressing lateral leakage current due to the ultra-thin channel, which is defined by the epitaxial layer thickness. Hetero-structure materials could be used in the source, drain, intermediate and/or epitaxial layers, which would help in creating a smaller effective band-gap for tunneling and a larger band-gap in the parasitic bulk region (i.e., intermediate region) between the source and the drain to prevent off-state leakage. In one example, the isolating semiconductor region between the source and drain regions has a band-gap greater than a band-gap of the epitaxial layer.

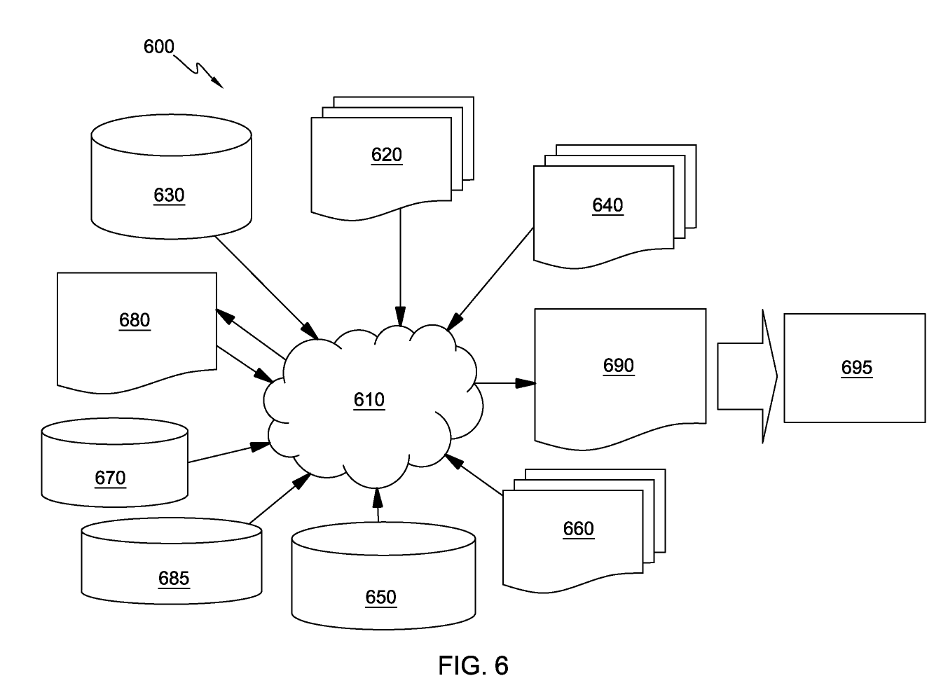

FIG. 6 depicts a block diagram of an exemplary design flow 600 used, for example, in semiconductor circuit design, simulation, test, layout, and manufacture. Design flow 600 includes processes and mechanisms for processing design structures or devices to generate logically or otherwise functionally-equivalent representations of the processes, design structures and/or devices described above and shown in FIGS. 2-5B. The design structures and/or processes generated by design flow 600 may be encoded on machine-readable transmission or storage media to include data and/or instructions that, when executed or otherwise processed on a data processing system, generate a logically, structurally, mechanically, or otherwise functionally-equivalent representation of hardware components, circuits, devices, or systems. Design flow 600 may vary, depending on the type of representation being designed. For example, a design flow for building an application specific integrated circuit (ASIC) may differ from a design flow for designing a standard component, or from a design flow for instantiating the design into a programmable array, for example, a programmable gate array (PGA) or field programmable gate array (FPGA) offered by Altera®, Inc., or Xilinx®, Inc.

FIG. 6 illustrates multiple such design structures, including an input design structure 620 that is processed by a design process 610. Design structure 620 may be a logical simulation design structure, generated and processed by design process 610 to produce a logically, equivalent-functional representation of a hardware device. Design structure 620 may also, or alternately, comprise data and/or program instruction that, when processed by design process 610, generate a functional representation of the physical structure of a hardware device. Whether representing functional and/or structural design features, design structure 620 may be generated using electronic computer-aided design (ECAD), such as implemented by a core developer/designer. When encoded on a machine-readable data transmission, gate array, or storage medium, design structure 620 may be accessed and processed by one or more hardware and/or software modules within design process 610 to simulate or otherwise functionally represent an electronic component, circuit, electronic or logic module, apparatus, device or system, such as those shown in FIGS. 2-5B. As such, design structure 620 may comprise files or other data structures, including human and/or machine-readable source code, compiled structures, and computer-executable code structures that, when processed by a design or simulation data processing system, functionally simulate or otherwise represent circuits or other levels of hardware logic design. Such data structures may include hardware-description language (HDL), design entities, or other data structures conforming to and/or compatible with lower-level HDL design languages, such as Verilog and VHDL, and/or higher-level design languages, such as C or C++.

Design process 610 may employ and incorporate hardware and/or software modules for synthesizing, translating, or otherwise processing a design/simulation functional equivalent of the components, circuits, devices or logic structures shown in FIGS. 2-5B to generate a netlist 680, which may contain design structures, such as design structure 620. Netlist 680 may comprise, for example, compiled or otherwise processed data structures representing a list of wires, discrete components, logic gates, control circuits, I/O devices, models, etc. that describes the connections to other elements and circuits in an integrated circuit design. Netlist 680 may be synthesized using an interactive process in which netlist 680 is re-synthesized one or more times, depending on design specifications and parameters for the device. As with other design structure types described herein, netlist 680 may be recorded on a machine-readable data storage medium, or programmed into a programmable gate array. The medium may be a non-volatile storage medium, such as a magnetic or optical disk drive, a programmable gate array, a compact flash, or other flash memory. Additionally, or in the alternative, the medium may be a system cache memory, buffer space, or electrically or optically conductive devices and materials on which data packets may be transmitted and intermediately stored via the Internet, or other networking suitable means.

Design process 610 may include hardware and software modules for processing a variety of input data structure types, including netlist 680. Such data structure types may reside, for example, within library elements 630 and include a set of commonly used elements, circuits, and devices, including modules, layouts, and symbolic representations, for a given manufacturing technology (e.g., different technology nodes, 32 nm, 45 nm, etc.). The data structure types may further include design specifications 640, characterization data 650, verification data 660, design rules 670, and test data files 685, which may include input test patterns, output test results, and other testing information. Design process 610 may further include, for example, standard mechanical design processes, such as stress analysis, thermal analysis, mechanical event simulation, process simulations for operations, such as casting, molding, and die press forming, etc. One of ordinary skill in the art of mechanical design can appreciate the extent of possible mechanical design tools and applications used in design process 610, without deviating from the scope and spirit of the invention. Design process 610 may also include modules for performing standard circuit design processes, such as timing analysis, verification, design rule checking, place and route operations, etc.

Design process 610 employs and incorporates logical and physical design tools, such as HDL, compilers and simulation module build tools to process design structure 620 together with some or all of the depicted supporting data structures, along with any additional mechanical design of data (if applicable), to generate a second design structure 690. Design structure 690 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 620, design structure 690 may comprise one or more files, data structures, or other computer-encoded data or instructions that reside on transmission or data storage media, and that when processed by an ECAD system, generate a logically or otherwise functionally-equivalent form of one or more of the embodiments of the invention. In one embodiment, design structure 690 may comprise a compiled, executable HDL simulation model that functionally simulates the processes and devices shown in FIGS. 2-5B.

Design structure 690 may also employ a data format used for the exchange of layout data of integrated circuits and/or symbolic data format (e.g., information stored in a GDSII (GDS2), GL1, OASIS, map files, or any other suitable format for storing such design data structures). Design structure 690 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce devices or structures, such as described above and shown in FIGS. 2-5B. Design structure 690 may then proceed to stage 695, where, for example, design structure 690 proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention.

What is claimed is:

1. A semiconductor device comprising:
a circuit structure comprising:
a first semiconductor region;
a second semiconductor region;
an intermediate region disposed between the first semiconductor region and the second semiconductor region; and
an epitaxial layer extending at least partially between the first semiconductor region and the second semiconductor region over or alongside of the intermediate region; and
a gate electrode for gating the circuit structure, the epitaxial layer of the circuit structure being disposed at least partially between the gate electrode and at least one of the first semiconductor region, the intermediate region, or the second semiconductor region.

2. The semiconductor device of claim 1, wherein the epitaxial layer physically contacts at least one of the first semiconductor region, the second semiconductor region, or the intermediate region.

3. The semiconductor device of claim 1, wherein the epitaxial layer comprises an epitaxially-grown, ultra-thin layer of semiconductor material, the ultra-thin layer of semiconductor material having a thickness less than or equal to 15 nanometers.

4. The semiconductor device of claim 1, wherein the semiconductor device comprises a tunneling field-effect transistor, with the first semiconductor region of the circuit structure being a source region of the tunneling field-effect transistor, and the second semiconductor region of the circuit structure being a drain region of the tunneling field-effect transistor, and wherein the epitaxial layer comprises a tunneling region of the tunneling field-effect transistor.

5. The semiconductor device of claim 4, wherein the tunneling field-effect transistor is a vertical tunneling field-effect transistor, and wherein the circuit structure comprises a stacked circuit structure comprising the first semiconductor region, the intermediate region and the second semiconductor region, and wherein the epitaxial layer extends along a sidewall of the stacked circuit structure.

6. The semiconductor device of claim 4, wherein the intermediate region comprises a large band-gap semiconductor region, the large band-gap semiconductor region having a band-gap greater than that of the epitaxial layer.

7. The semiconductor device of claim 1, wherein the circuit structure comprises a hetero-structure, with the epitaxial layer comprising a second conductivity type opposite to a first conductivity type of at least one of the first semiconductor region or the second semiconductor region of the circuit structure.

8. The semiconductor device of claim 1, wherein a channel length through the epitaxial layer is related to a thickness of the intermediate region between the first semiconductor region and the second semiconductor region.

9. The semiconductor device of claim 1, wherein the intermediate region comprises at least one of indium phosphate or indium aluminum arsenic.

10. A tunnel field-effect transistor comprising:
a circuit structure comprising:
a source region;
a drain region;
an intermediate region disposed between the source region and the drain region;
an epitaxial layer extending at least partially between the source region and the drain region over or alongside of the intermediate region, the epitaxial layer comprising a tunneling region and a channel region of the tunneling field-effect transistor; and
a gate electrode for gating the circuit structure, the epitaxial layer of the circuit structure being disposed at least partially between the gate electrode and at least one of the source region, the intermediate region, or the drain region.

11. The tunnel field-effect transistor of claim 10, wherein the epitaxial layer physically contacts at least one of the source region, the drain region, or the intermediate region.

12. The tunnel field-effect transistor of claim 10, wherein the intermediate region comprises a large band-gap semiconductor region, the large band-gap semiconductor region having a band-gap greater than that of the epitaxial layer.

13. The tunnel field-effect transistor of claim 10, wherein the circuit structure comprises a hetero-structure, with the epitaxial layer comprising a second conductivity type opposite to a first conductivity type of at least one of the source region or the drain region.

14. The tunnel field-effect transistor of claim 10, wherein the circuit structure comprises a stacked circuit structure including the source region, the drain region, and the intermediate region disposed therebetween, and wherein the epitaxial layer extends along a sidewall of the stacked circuit structure.

15. The tunnel field-effect transistor of claim 14, wherein the epitaxial layer comprises an epitaxially-grown, ultra-thin layer of semiconductor material grown from at least one of the source region, the drain region, or the intermediate region.

16. The tunnel field-effect transistor of claim 10, wherein a channel length through the channel region of the epitaxial layer is related to a thickness of the intermediate region between the source region and the drain region.

17. A method of fabricating a semiconductor device comprising:
fabricating a circuit structure, wherein fabricating the circuit structure comprises:
providing a first semiconductor region, a second semiconductor region, and an intermediate region disposed between the first semiconductor region and the second semiconductor region;
epitaxially growing an epitaxial layer to extend at least partially over or alongside of the intermediate region, wherein the epitaxial layer extends at least partially between the first semiconductor region and the second semiconductor region over or alongside of the intermediate region; and
providing a gate electrode for gating the circuit structure, wherein the epitaxial layer of the circuit structure is disposed at least partially between the gate electrode and at least one of the first semiconductor region, the intermediate region, or the second semiconductor region.

18. The method of claim 17, wherein epitaxially growing the epitaxial layer comprises epitaxially growing an ultra-thin layer of semiconductor material, the ultra-thin layer of semiconductor material having a thickness less than or equal to 15 nanometers.

19. The method of claim 17, wherein fabricating the circuit structure comprises fabricating the circuit structure as a tunnel field-effect transistor, with the first semiconductor region of the circuit structure being a source region of the tunneling field-effect transistor, and the second semiconductor region of the circuit structure being a drain region of the tunneling field-effect transistor, and wherein the epitaxial layer comprises a tunneling region of the tunneling field-effect transistor, and the intermediate region comprises a large band-gap semiconductor region, the large band-gap semiconductor region having a band-gap greater than that of the epitaxial layer.

20. The method of claim 19, wherein fabricating the circuit structure comprises fabricating the circuit structure as a vertical tunneling field-effect transistor, and wherein the circuit structure comprises a stacked circuit structure comprising the source region, the drain region, and the large band-gap semiconductor region, and wherein the epitaxial layer extends along a sidewall of the stacked circuit structure.

21. The method of claim 17, wherein fabricating the circuit structure comprises fabricating the circuit structure as a hetero-structure, with the epitaxial layer comprising a second conductivity type opposite to a first conductivity type of at least one of the first semiconductor region or the second semiconductor region of the circuit structure.
